(19) United States
(12) Patent Application Publication
(10) Pub. No.: US 2002/0042199 A1
(43) Pub. Date: Apr. 11, 2002

(54) Polishing by CMP for optimized planarization

(76) Inventors: Jinru Bian, Newark, DE (US); Tirthankar Ghosh, Oreland, PA (US); Terence M. Thomas, Newark, DE (US)

Correspondence Address: Gerald K. Kita, Rodel Holdings, Inc., Suite 1300, 1105 North Market Street, Wilmington, DE, 19899, US

(21) Appl. No.: 09/956,680

(22) Filed: Sep. 20, 2001

Related U.S. Application Data
(60) Provisional application No. 60/233,818, filed on Sep. 20, 2000.

(51) Int. Cl. C09K 13/06; H01L 21/302; H01L 21/461

(52) U.S. Cl. 438/692; 252/79.4

(57) ABSTRACT

A polishing composition for polishing with a polishing pad to remove a metal layer from a semiconductor wafer having the metal layer and further having recessed metal in trenches, the composition having a concentration of BTA selected to maximize the rate of change in the removal rate of a metal layer with increases in downforce exerted by a polishing pad during polishing, which maximizes a difference between the removal rate of the metal layer and the removal rate of the recessed metal in trenches.

### CROSS REFERENCE TO RELATED APPLICATION

This application claims the benefit of provisional application No. 60/223,818 filed Sep. 20, 2000.

### FIELD OF THE INVENTION

The invention relates to a polishing composition and a method for polishing a semiconductor wafer, according to chemical mechanical planarization, CMP, to remove a metal layer from the semiconductor wafer.

### BACKGROUND OF THE INVENTION

A polishing operation known as CMP is performed to remove a metal layer from an underlying material on a semiconductor wafer. CMP is performed by polishing the metal layer with a polishing pad and with an aqueous polishing composition. The polishing pad impinges the metal layer, and exerts a downforce against the metal layer. Abrasion of the metal layer is produced by relative movement of the polishing pad and the wafer. The polishing pad exerts less downforce against the recessed metal in trenches, because the recessed metal is below the elevation of the metal layer. Thus, the recessed metal in trenches is subjected to less downforce and abrasion than the metal layer. Polishing the metal layer causes removal of the metal layer at a relatively high removal rate, i.e., a relatively high rate of removal. Although removal of the recessed metal in trenches is unavoidable, the recessed metal in trenches is removed at a substantially lower removal rate. A desired, planarization of the semiconductor substrate is attained after the metal layer has been removed from an underlying material of the substrate by polishing, and the recessed metal in trenches has been polished to become substantially planar with a surface of the underlying material.

A polishing operation by CMP tends to produce dishing. Dishing is observed as comprising concavities in the recessed metal in trenches, which prevents optimized planarization, and which further causes electrical signal attenuation when the recessed metal in trenches are in use as electrical interconnects for transmitting electrical signals. Dishing is required to be minimized during the polishing operation, so as to attain both optimized planarization, and minimized signal attenuation. However, attempts to minimize dishing have been deterred. More specifically, as the polishing operation is performed to remove successive amounts of the metal layer, the elevation of the metal layer is successively reduced. As the reduced elevation of the metal layer approaches the low elevation of the recessed metal in trenches, the polishing pad exerts an increasing downforce against the recessed metal in trenches, which increases the removal rate of the recessed metal in trenches. Such an increased removal rate tends to increase dishing, and prevents the recessed metal from becoming substantially planar with the surface of the underlying material.

While the metal layer is successively reduced to a lower elevation during a polishing operation, a respective downforce exerted against the recessed metal in trenches increases, which increases the removal rate of the recessed metal in trenches, and which deters optimum planarization and tends to cause dishing. However, by maximizing a difference between the removal rate of the metal layer and the removal rate of the recessed metal in trenches, the metal layer is removed quickly, such that both planarization and minimized dishing are attained.

Accordingly, a need exists for an invention that will maximize a difference between the removal rate of a metal layer by polishing, and the removal rate of recessed metal in trenches, to minimize removal of the recessed metal in trenches and minimize dishing.

### SUMMARY OF THE INVENTION

The invention provides a polishing composition for a polishing fluid, and a method of polishing a metal layer on a semiconductor wafer, which maximizes a difference between a removal rate of the metal layer and a removal rate of recessed metal in trenches of the semiconductor wafer, as the elevation of the metal layer is lowered by polishing to approach a low elevation of the recessed metal in trenches.

### DESCRIPTION OF THE DRAWINGS

Embodiments of the invention will now be described by way of example with reference to the accompanying drawings, according to which:

FIG. 1 is an enlarged fragmentary cross section of a semiconductor wafer having a metal layer to be removed by polishing with a polishing pad and a polishing fluid, and further disclosing recessed metal in one of multiple trenches;

FIG. 2 is a view similar to FIG. 1, and discloses a desired, planarization of the semiconductor substrate attained when the metal layer has been removed from an underlying material of the substrate by polishing, and the recessed metal in trenches has been polished to become substantially planar with a surface of the underlying material with minimized dishing.

FIG. 3 is a graph of removal rates of copper metal corresponding to changes in downforce exerted by a polishing pad on the copper metal, the graph further disclosing curves indicating rates of change of the removal rates corresponding with various concentrations of BTA in a polishing fluid that is used during polishing to remove the copper metal from a semiconductor wafer.

### DESCRIPTION OF THE EMBODIMENTS

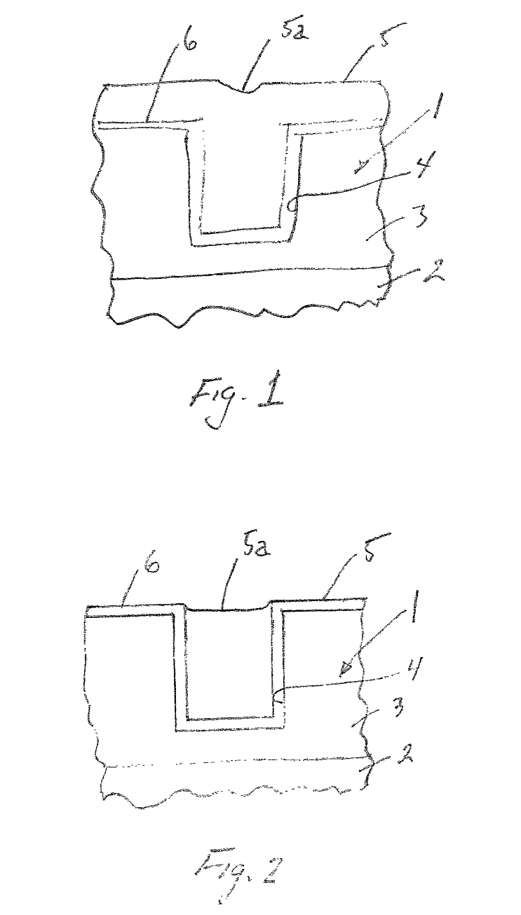

With reference to FIG. 1, a known semiconductor wafer 1 comprises, a slice of silicon 2 on which is deposited a dielectric layer 3 having recessed trenches 4 therein. Further, a barrier film 6 of tantalum nitride, for example, is deposited over the underlying dielectric layer 3. A metal layer 5 is deposited over the underlying barrier film 6. The metal layer 5 is deposited in sufficient thickness to fill the recessed trenches 4 with recessed metal 5a. CMP is performed by polishing a surface of the wafer 1 with a polishing pad and with a polishing fluid, to remove the metal layer 5 from an underlying material of the wafer 1, and to polish the recessed metal 5a in trenches 4 to an elevation that is substantially planar with the surface of the underlying material of the wafer 1. A second step CMP polishing operation may be performed to remove the barrier film 6 from the underlying dielectric layer 3. The second step CMP polishing operation follows a first step CMP polishing operation that removes the metal layer 5 from the underlying barrier film 6. Alternatively, a single step CMP polishing operation may be performed to remove the metal layer 5, well as the barrier film 6, from the underlying dielectric layer 3. The invention will be described by describing removal of the metal layer 5, which applies to both, the first step CMP polishing operation, and the single step CMP polishing operation. The recessed metal 5a in trenches 4 provide conducting electrical circuit interconnects for transmitting electrical signals. For example, the metal of the metal layer 5, and of the recessed metal 5a in trenches 4, comprises copper, which requires a polishing composition suitable to remove the metal layer 5 of copper by CMP.

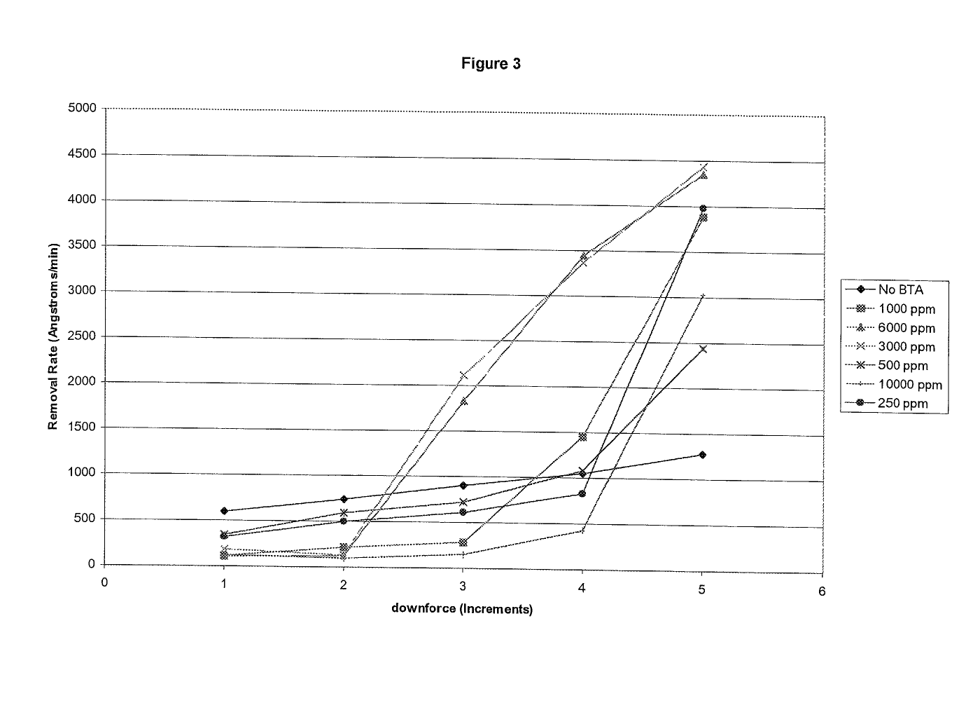

A polishing composition according to the invention minimizes dishing during performance of a polishing operation to remove the metal layer 5. An aqueous polishing composition was prepared by blending together the following constituents: 0.22 parts malic acid, a complexing agent of copper to provide copper ion complexes, 9.0 parts hydrogen peroxide, an oxidizer of copper metal, with water to provide 100 parts of the composition and the pH was adjusted to 3.1. Then 0.09 parts polyacrylic acid having a number average molecular weight of 250,000 and 0.09 parts polyacrylic acid having a number average molecular weight of 30,000 were added. Polyacrylic acid is an accelerant that increases the removal rate of copper metal by CMP polishing. Respective samples of the polishing composition were prepared. Respective concentrations of BTA, benzotriazole, were added to the respective samples. Tests were performed by polishing test wafers 1 changing the downforce in increments 1-5, using samples with different concentrations of BTA, and the results plotted on a graph disclosed by FIG. 3.

Each of the test wafers 1 polished comprised, a silicon slice 2 having a silicon dioxide dielectric layer 3 with recessed copper metal 5a in trenches 4. The trenches 4 had respective widths selected from various widths of 10 μm, 25 μm and 100 μm.

A Mira polishing machine was used under the following polishing conditions: 100 rpm platen speed and 90 rpm head speed for 40 seconds. The downforce on the metal layer 5 was varied in equal increments of 1-5, as shown on the graph of FIG. 3. For example, increment 5 corresponds to a downforce of 5 psi, pounds per square inch. The down force is defined as a measured pressure exerted by the polishing pad on the wafer 1 covered by the metal layer 5. The polishing pad used was a Metals 26 pad commercially available from Rodel, Inc., Newark, Del., USA, and described in U.S. Pat. No. 6,022,268. The pad was pre-conditioned for 30 minutes with a 100 grit diamond disk (manufactured by Abrasives Technology, Inc.) and conditioned for 20 seconds between polishing of test wafers.

The BTA in the samples of polishing composition chemically reacts as an inhibitor. The BTA adsorbs on recessed metal 5a in trenches 4, and inhibits formation of copper oxide ions that would result from the recessed metal 5a in trenches 4 being in contact with dissolved oxygen in the polishing composition. The recessed metal 5a in trenches 4 is inhibited from forming oxide ions that are susceptible to be removed by a combination of, abrasion applied by the polishing pad to remove the oxide ions, and dissolution of the removed oxide ions in the polishing composition. Thus, BTA in the polishing composition inhibits removal of recessed metal 5a in trenches 4 during polishing of the metal layer 5. With reference to the graph disclosed by FIG. 3, various curves on the graph are plotted to correspond with different concentrations of BTA in respective polishing compositions.

With reference to the graph disclosed by FIG. 3, each curve is constructed by plots indicating removal rates of the metal layer 5 as a function of polishing with a downforce that varies in increments 1-5. While the polishing operation is performed to remove the metal layer 5, the metal layer 5 is successively reduced in elevation to approach the low elevation of the recessed metal 5a in trenches 4, which causes successive increases in the downforce exerted on the recessed metal 5a in trenches 4. Accordingly, each curve can be interpreted as disclosing, both the removal rate of the metal layer 5 while a downforce of increment 5 is exerted thereon, and the removal rate of the recessed metal 5a in trenches 4 while the metal layer 5 is polished and reduced to lower elevations, which causes a respective downforce exerted on the recessed metal 5a to successively increase from increment 1 to increment 4. Further, while the metal layer is polished and reduced in elevation to approach the low elevation of the recessed metal 5a, the respective downforce exerted on the recessed metal 5a increases from increment 4 to approach increment 5.

With further reference to FIG. 3, the incline or slope of each curve indicates the rate of change of the removal rate of copper metal, as the downforce varies in increments 1-5. For example, a relatively steep incline or slope on a curve indicates a relatively large rate of change in the removal rate, as the downforce successively increases in increments. The graph of FIG. 3 indicates that between the increments 4 and 5 of downforce, a relatively steep incline or slope is on each of the respective curves that correspond to, both a selected concentration of BTA at 3000 ppm, parts per million, and a selected concentration of BTA at 250 ppm. Thus, a polishing composition is provided with either such selected concentration of BTA that maximizes the rate of change in the removal rate of the metal layer 5 with changes in the downforce between increments 4 and 5.

The downforce between increments 4 and 5 become exerted on the recessed metal 5a in trenches 4, while the metal layer 5 is polished and reduced to lower elevations approaching the low elevation of the recessed metal 5a. Accordingly, the difference between the removal rate of the metal layer 5 and the removal rate of the recessed metal 5a in trenches 4 is maximized between increments 4 and 5 of downforce, which corresponds to an occurrence wherein, the lowered elevation of the metal layer 5 approaches the low elevation of the recessed metal 5a in trenches 4. Before the lowered elevation of the metal layer 5 approaches the low elevation of the recessed metal 5a in trenches 4, the elevation of the metal layer 5 is relatively far from the elevation of the recessed metal 5a in trenches 4, and causes a corresponding reduced downforce, of an increment of about 4 or less, exerted on the recessed metal 5a in trenches. For example, as disclosed by the graph, FIG. 4, the curve corresponding to a BTA concentration of 250 ppm indicates a removal rate of less than 1000 Angstroms per minute when the downforce is reduced from an increment above 4 to an increment of 1, despite the incline or slope of the curve being below its desired maximum that occurs when the lowered elevation of the metal layer 5 approaches the low elevation of the recessed metal 5a in trenches 4, and the corresponding downforce on the recessed metal 5a increases from increment 4 to approach increment 5. Advantageously, the removal rate of recessed metal 5a in trenches 4 is minimized, for example, below 1000 Angstroms per minute, even when the incline or slope of the curve is below its desired maximized incline or slope at the occurrence wherein, the lowered elevation of the metal layer 5 approaches the low elevation of the recessed metal 5a. The last residual amounts of the metal layer 5 to be removed, is polished with a reduced downforce, for example, a downforce reduced from increment 5, such that minimized removal of the recessed metal 5 in trenches 4 occurs when polishing at such a reduced downforce.

An unanticipated surprising result of the invention is, that a polishing composition and a polishing process provides a maximized rate of change in the removal rate of the metal layer 5 with variations in downforce.

Another unanticipated surprising result is, that dishing is minimized by providing an embodiment of a polishing composition having a selected concentration of an oxide inhibitor that maximizes the rate of change in the removal rate of the metal layer 5 with variations in downforce.

An embodiment of the invention provides a polishing composition with a concentration of an oxide inhibitor selected to maximize the rate of change in the removal rate of the metal layer 5 with changes in downforce exerted by a polishing pad during polishing, as the elevation of the metal layer 5 is lowered by polishing to approach a low elevation of the metal 5a in trenches 4, which maximizes a difference between the removal rate of the metal layer 5 and the removal rate of the recessed metal 5a in trenches 4 to minimize dishing.

Other embodiments and modifications of the invention are intended to be covered by the spirit and scope of the appended claims.

What is claimed is:

1. A polishing composition for a polishing fluid that removes metal from a metal layer on a semiconductor wafer by polishing the metal layer with the polishing fluid and a polishing pad, the polishing composition comprising: an inhibitor of oxidation of the metal, the inhibitor being of selected concentration that maximizes a difference between a removal rate of the metal layer and a removal rate of recessed metal in trenches of the semiconductor wafer, as the elevation of the metal layer is lowered by polishing to approach a low elevation of the recessed metal in trenches.

2. The polishing composition as recited in claim 1 wherein, the inhibitor is BTA.

3. The polishing composition as recited in claim 1 wherein, the inhibitor is BTA of 3000 ppm, parts per million, concentration.

4. The polishing composition as recited in claim 1 wherein, the inhibitor is BTA of 250 ppm, parts per million, concentration.

5. The polishing composition as recited in claim 1, wherein the polishing composition further comprises: a complexing agent of the metal in the metal layer, an oxidizer of the metal in the metal layer with to provide 100 parts of the composition, a pH adjusted to 3.1, and an accelerator.

6. A method for polishing with a polishing composition and a polishing pad to remove metal from a metal layer on a semiconductor wafer having the metal layer and further having recessed metal in trenches, comprising the step of:
providing the polishing composition with a selected concentration of an inhibitor of oxidation of the metal, the concentration of the inhibitor being selected to maximize the rate of change in the removal rate of the metal layer with changes in downforce exerted by a polishing pad during polishing, as the elevation of the metal layer is lowered by polishing to approach a low elevation of the recessed metal in trenches, which maximizes a difference between the removal rate of the metal layer and the removal rate of the recessed metal in trenches, and
polishing the metal layer with the polishing pad and with the polishing composition having said concentration of the inhibitor.

7. The method as recited in claim 6 wherein, the step of, providing the polishing composition with a selected concentration of an inhibitor of oxidation of the metal, further comprises: providing the polishing composition with a concentration of BTA of 3000 ppm, parts per million.

8. The method as recited in claim 6 wherein, the step of, providing the polishing composition with a selected concentration of an inhibitor of oxidation of the metal, further comprises: providing the polishing composition with a concentration of BTA of 250 ppm, parts per million.

9. The method as recited in claim 6, further comprising the step of: providing the polishing composition with; a complexing agent of the metal in the metal layer, an oxidizer of the metal in the metal layer with to provide 100 parts of the composition, a pH adjusted to 3.1, and an accelerator.

10. A polishing composition for polishing with a polishing pad to remove metal from a metal layer on a semiconductor wafer, having both the metal layer and recessed metal in trenches, the polishing composition comprising: an inhibitor of oxidation of the metal, the inhibitor having a concentration selected to maximize the rate of change in the removal rate of the metal layer with changes in downforce exerted by a polishing pad during polishing, as the elevation of the metal layer is lowered by polishing to approach a low elevation of the recessed metal in trenches, which maximizes a difference between a removal rate of the metal layer and a removal rate of the recessed metal in trenches.
